(19) United States
(12) Patent Application Publication
(10) Pub. No.: US 2015/0173178 A1
(43) Pub. Date: Jun. 18, 2015

(54) THERMOCHROMIC SOLDER MASK FOR ELECTRONIC DEVICES

(71) Applicant: ECHOSTAR TECHNOLOGIES L.L.C., Englewood, CO (US)

(72) Inventor: Adam Charles Morzos, Parker, CO (US)

(21) Appl. No.: 14/104,186

(22) Filed: Dec. 12, 2013

(51) Int. Cl. H05K 1/02; H05K 3/34; H05K 1/18

(52) U.S. Cl. CPC H05K 1/0274; H05K 1/181; H05K 3/3452; H05K 2201/2081

(57) ABSTRACT

An electronic device is disclosed herein. In accordance with certain implementations, the electronic device includes a printed circuit board having electrically conductive traces formed thereon. The electronic device also includes a thermochromic solder mask layer overlying the electrically conductive traces. The thermochromic solder mask layer changes color in response to temperature changes associated with operation of the electronic device. The thermochromic characteristics of the solder mask layer are useful for purposes of indicating overheating of the electronic device, the conductive traces, or a region of the printed circuit board.

### TECHNICAL FIELD

Embodiments of the subject matter described herein relate generally to electronic devices and circuits. More particularly, embodiments of the subject matter relate to electronic devices that utilize a thermochromic solder mask on a circuit board or substrate.

### BACKGROUND

Electronic devices usually include a circuit board or substrate that carries the necessary electronic components, conductive interconnects, input/output interfaces, wires, or the like. For example, printed circuit boards are found in many common systems and devices, including computers, appliances, video system set-top boxes, home entertainment equipment, toys, and automobiles. Electronic devices and/or their circuit boards can be subjected to a variety of tests during manufacturing, development, or scheduled maintenance. For example, an electronic device may be subjected to functional tests that simulate real world operating conditions. As another example, an electronic device may subjected to a debugging procedure to diagnose or identify faults, problems, or defects. In this regard, it may be important to determine whether or not a component, a region, or a conductive trace is overheating, because overheating may indicate a faulty circuit design, a defective electronic component or chip, a short circuit, or the like.

Accordingly, it is desirable to have a convenient and efficient way to indicate the temperature of an electronic circuit board (or regions of the board). In addition, it is desirable to have a circuit board design that generates a visual indication of an overheating condition. Furthermore, other desirable features and characteristics will become apparent from the subsequent detailed description and the appended claims, taken in conjunction with the accompanying drawings and the foregoing technical field and background.

### BRIEF SUMMARY

An exemplary embodiment of an electronic device is presented here. The electronic device includes a printed circuit board having electrically conductive traces formed thereon, and a thermochromic solder mask layer. The thermochromic solder mask layer overlies at least the electrically conductive traces, and the thermochromic solder mask layer changes color in response to temperature changes associated with operation of the electronic device.

Another exemplary embodiment of an electronic device is also presented here. The electronic device includes a circuit substrate, at least one electronic component, device, or element on the circuit substrate, and a layer of thermochromic material formed on the circuit substrate and in close proximity to the at least one electronic component, device, or element. The layer of thermochromic material changes color in response to overheating of the at least one electronic component, device, or element.

Yet another exemplary embodiment of an electronic device is presented here. The electronic device includes a circuit substrate, an electronic circuit formed on the circuit substrate, and a thermochromic solder mask layer overlying at least a portion of the electronic circuit. The thermochromic solder mask layer changes color in response to activation of the electronic circuit.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a top/bottom view of a circuit board configured in accordance with an embodiment of the invention;

FIG. 2 is a cross sectional view of a portion of the circuit board, as viewed from line 2-2 in FIG. 1;

FIG. 3 is a top/bottom view of the circuit board shown in FIG. 1, wherein an area of the circuit board is overheated;

FIG. 4 is a top/bottom view of the circuit board shown in FIG. 1, wherein a conductive trace of the circuit board is overheated; and

FIG. 5 is a top/bottom view of a circuit board in an activated state.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

The subject matter presented here relates to a thermochromic solder mask layer that is applied to: an electronic circuit board or substrate; an electronic device, chip, or package; an electrically conductive trace or element; or the like. As used here, “thermochromic” refers to the property or characteristic of a material, substance, composition, or element that results in a change in color with a change in temperature. This property (known as “thermochromism”) may be defined as “the property of substances to change color due to a change in temperature” (see www.wikipedia.com). This property may also be defined as “a phenomenon in which certain dyes made from liquid crystals change color reversibly when their temperature is changed” (see www.thefreedictionary.com). In certain embodiments, a thermochromic solder mask layer is applied overlying at least a portion of a printed circuit board such that the solder mask layer changes color in response to temperature change. More specifically, the thermochromic properties of the solder mask material are chosen such that the solder mask changes color to indicate overheating of the circuit board or components mounted to or integrated in the circuit board.

For the sake of brevity, conventional techniques and aspects related to electronic circuit design, circuit board fabrication, solder mask materials, and thermochromic compositions may not be described in detail herein. Thermochromic liquid crystals, leuco dyes, polymers, inks, and compositions are generally available, and the solder mask material described here can be manufactured, treated, or selected such that it exhibits the desired thermochromic properties and characteristics.

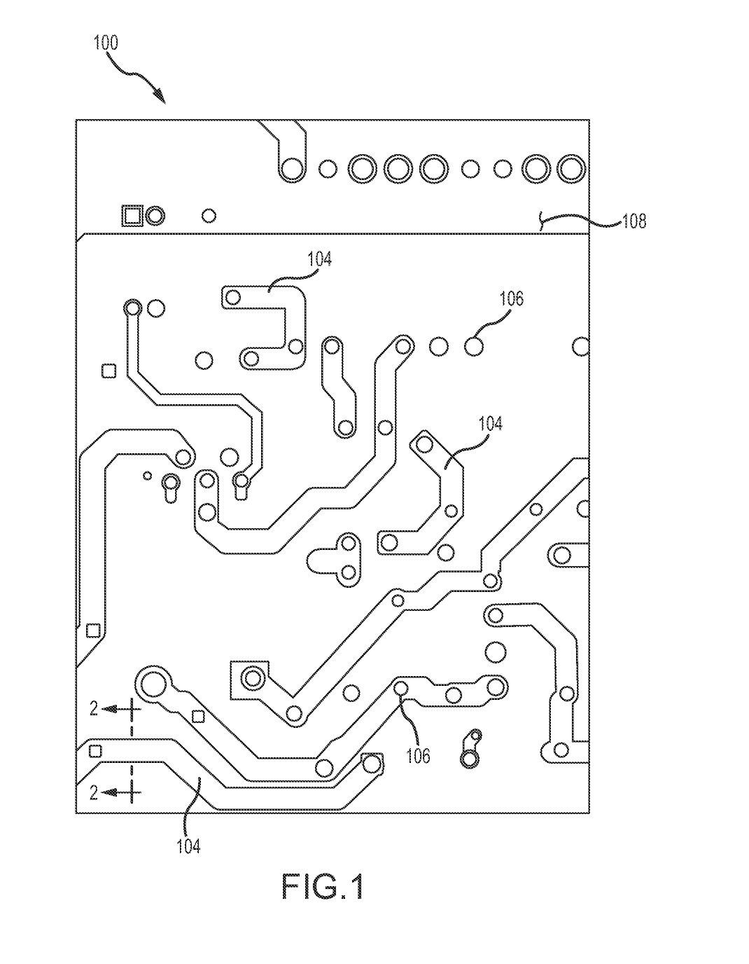

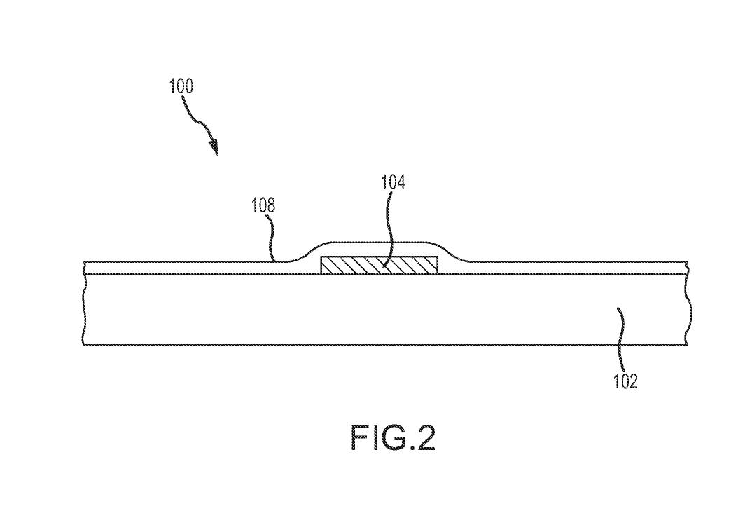

Referring now to the drawings, FIG. 1 is a top/bottom view of a circuit board 100 configured in accordance with an embodiment of the invention, and FIG. 2 is a cross sectional view of a portion of the circuit board 100, as viewed from line 2-2 in FIG. 1. The circuit board 100 may be designed and configured for use with any type of electronic device, system, component, or architecture, as desired for the intended application. For the sake of clarity and brevity, the host electronic device is not shown in the drawings.

The illustrated embodiment of the circuit board 100 includes, without limitation: a circuit substrate 102; electrically conductive traces 104 formed overlying the circuit substrate 102; vias 106 formed in the circuit substrate 102; and a thermochromic solder mask layer 108. The circuit substrate 102 is hidden from view in FIG. 1, and the portion of the circuit board 100 shown in FIG. 2 does not include any vias 106. The patterned lines depicted in FIG. 1 correspond to the conductive traces 104 (only a few of which are numbered in FIG. 1), and the circles or dots depicted in FIG. 1 correspond to the vias 106 (only a few of which are numbered in FIG. 1). Although not shown, any number of electronic components, devices, or elements may also be mounted to or incorporated into the circuit substrate 102. For example, any of the following items may be found on the circuit substrate 102: semiconductor chips; passive elements (resistors, capacitors, inductors); sensors; transducers; logic gates; switches; microelectromechanical devices; or the like. Thus, the circuit board 100 is suitably configured such that at least one electronic circuit is formed on the circuit substrate 102.

The circuit substrate 102 represents the supporting structure of the circuit board 100. In certain embodiments, the circuit substrate 102 is fabricated from a dielectric material such as plastic, fiberglass, ceramic, or the like. In this regard, the circuit substrate 102 may be fabricated in accordance with well-known and well-established printed circuit board technology. For example, the circuit substrate 102 may be formed as a laminate construction such as an FR-4 material, wherein the conductive traces 104 are etched from a metal layer of the laminate material. In alternative embodiments, the circuit substrate 102 may be utilized in a flip-chip package, a surface mount architecture, or the like. For a flip-chip package, the electronic device may include one or more semiconductor chip devices or components electrically and physically coupled to the electrically conductive traces, e.g., using ball grid array technology.

The conductive traces 104 may be formed directly on the circuit substrate 102. In accordance with standard printed circuit board fabrication techniques, the conductive traces 104 may be formed by etching a metal layer (such as a copper layer) into the desired pattern. In alternative embodiments, the conductive traces 104 could be formed using various well-known electronic device fabrication techniques, such as conductive material deposition, photolithography, etching, and the like. The resulting pattern provides the necessary electrical interconnections and conductive features for the circuit board 100.

The vias 106 are typically fabricated as conductive through holes that facilitate interconnections between layers of the circuit board 100 (e.g., from the top surface to the bottom surface) and/or soldering of components to the circuit board 100. Each via 106 may be formed as a plated hole, which can accommodate solder as needed. After fabrication of the electronic device, most of the vias 106 will be filled with solder or some other conductive material.

The thermochromic solder mask layer 108 is formed overlying at least the electrically conductive traces 106. In practice, the thermochromic solder mask layer 108 may be applied to both major surfaces/sides of the circuit board 100. In accordance with conventional solder mask technology, a thin coating of thermochromic material protects the electrically conductive traces 104 of the circuit board 100, and has openings in areas where electrical connections are needed or other areas where the bare conductor material (e.g., copper) is to be exposed. The solder mask layer 108 primarily functions to help keep solder in the correct areas when the electronic device is assembled.

The thermochromic solder mask layer 108 may include an insulating carrier material (such as lacquer, paint, epoxy, resin, vinyl, or other coating) having an appropriate thermochromic substance suspended or otherwise mixed into the carrier material. In certain embodiments, the thermochromic solder mask layer 108 is directly applied to (and formed on) an exposed surface of the circuit board 100 such that the thermochromic solder mask layer 108 coats the desired portion of the circuit board 100. In practice, the thermochromic solder mask layer 108 can be selectively applied to the desired areas, while leaving other areas or regions unprotected. For example, the thermochromic solder mask material may be applied to the surface of the circuit board 100 using silk screen techniques such that the conductive traces 104 and the intervening areas of the circuit substrate 102 are covered, while leaving the vias 106 and a small perimeter area around the vias 106 uncovered.

The thermochromic solder mask layer 108 changes color in response to temperature changes associated with the operation of the host electronic device. More specifically, the solder mask layer 108 changes color at temperatures higher than a threshold temperature, which may be engineered, selected, or chosen to suit the needs of the given application. In certain embodiments, the threshold temperature of the solder mask layer 108 may be approximately 70 degrees Celsius, which is indicative of a typical normal operating temperature of consumer-based electronic devices. As used here, “approximately 70 degrees Celsius” contemplates a range that is near 70 degrees, such as a range of 60 to 80 degrees, or it may contemplate a percentage change relative to 70 degrees, such as 70 degrees±10%. Although 70 degrees Celsius is provided here as one realistic example, it should be appreciated that the threshold color-changing temperature could be much lower or higher than 70 degrees, depending on the particular application and operating environment. The specific threshold temperature that initiates color change in the thermochromic solder mask layer 108 can be selected such that the solder mask layer 108 is effective at indicating overheating of at least one electronic component, device, element, or region of the circuit board 100. For example, a color shift in the solder mask layer 108 may indicate an overheating condition associated with a specific conductive trace 104, a specific electronic component that is mounted to the circuit board 100, or the like. Accordingly, the thermochromic solder mask layer 108 should be (and preferably is) formed on the circuit substrate 102 within close proximity to the components, devices, elements, or areas of interest, e.g., locations where it is desirable to monitor for overheating.

In certain embodiments, the thermochromic solder mask layer 108 exhibits a first color that is indicative of normal operating temperatures of the electronic device, and exhibits a second color (that is visibly distinguishable from the first color) that is indicative of unusually high operating temperatures of the electronic device. Thus, the particular type of thermochromic solder mask material can be chosen or fabricated in a way that anticipates the expected normal operating temperature(s) of the electronic device, the circuit board 100, and/or the individual components or features on the circuit board 100. Although most available thermochromic substances are characterized by two different colors and one threshold temperature range, the thermochromic solder mask layer 108 could be fabricated using more than one thermochromic substance and/or using a suitably engineered thermochromic substance that has more than two color shifting transition points and more than two distinguishable colors. Accordingly, the thermochromic properties and characteristics of the solder mask layer 108 can be calibrated as needed to enable the solder mask layer 108 to serve as an overheating indicator for the given electronic device, the conductive traces 106, the circuit board 100, etc.

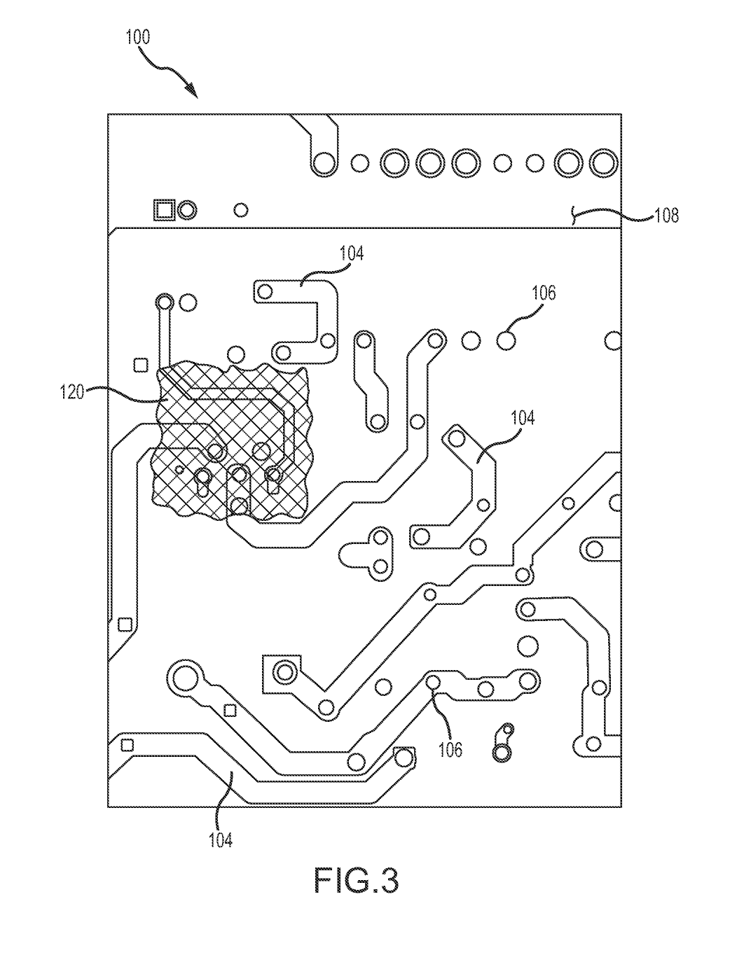

FIG. 3 is a top/bottom view of the circuit board 100 in an overheated state. For this example, an area 120 represents an overheated region of the circuit board 100. The area 120 corresponds to a section of the thermochromic solder mask layer 108 that has transitioned from its nominal color to a visually distinguishable second color that indicates higher temperature. In contrast, the remaining portion of the solder mask layer 108 has retained its nominal “normal operating temperature” color. Although not separately depicted in FIG. 3, there might be a color gradient zone between the area 120 and the outer portions of the thermochromic solder mask layer 108, wherein the gradient zone exhibits color shading that gradually changes from the high temperature color to the nominal color. Thus, the area 120 serves as a high temperature indicator that can be quickly and easily detected by a technician, a user, or a test engineer. The root cause of the high temperature condition is unimportant for purposes of this description. That said, the area 120 may appear in response to a failed conductive trace 104, a conductive trace 104 that is too thin, a defective semiconductor chip, an electronic component that is overloaded, or the like.

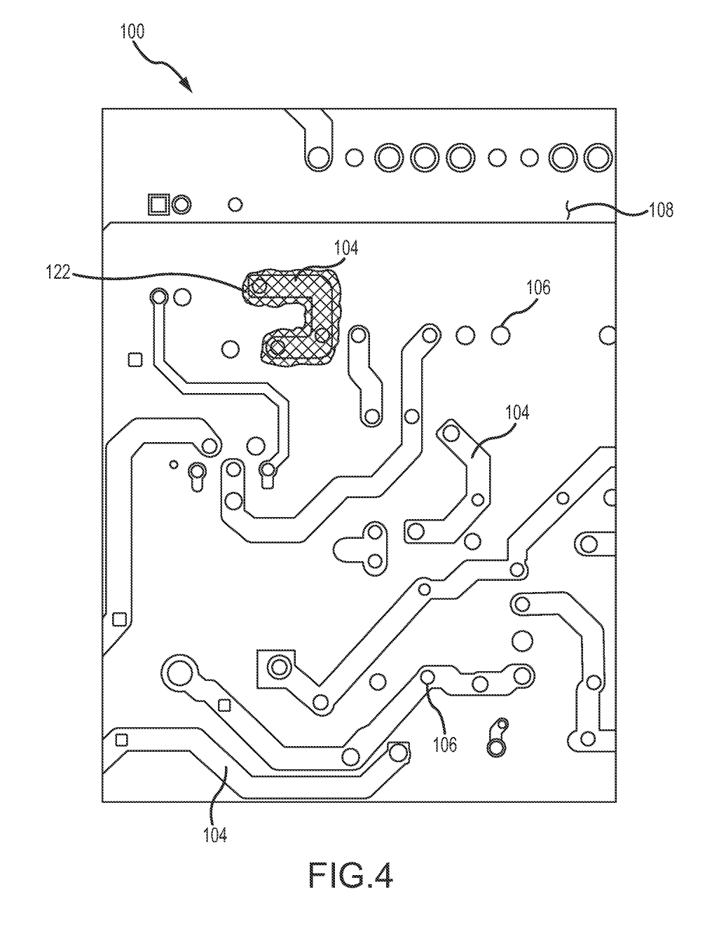

FIG. 4 is a top/bottom view of the circuit board 100 in a state where overheating is concentrated at only one conductive trace 104. For this example, the thermochromic characteristics of the solder mask layer 108 and/or the thermal properties of the conductive traces 104 result in a highly defined and highly resolved “hot zone” as indicated by the color-shifted area 122 of the solder mask layer 108. In contrast to the example shown in FIG. 3, the area 122 closely and precisely tracks the outline of the underlying conductive trace 104, thus making it easy to determine the source of the overheating.

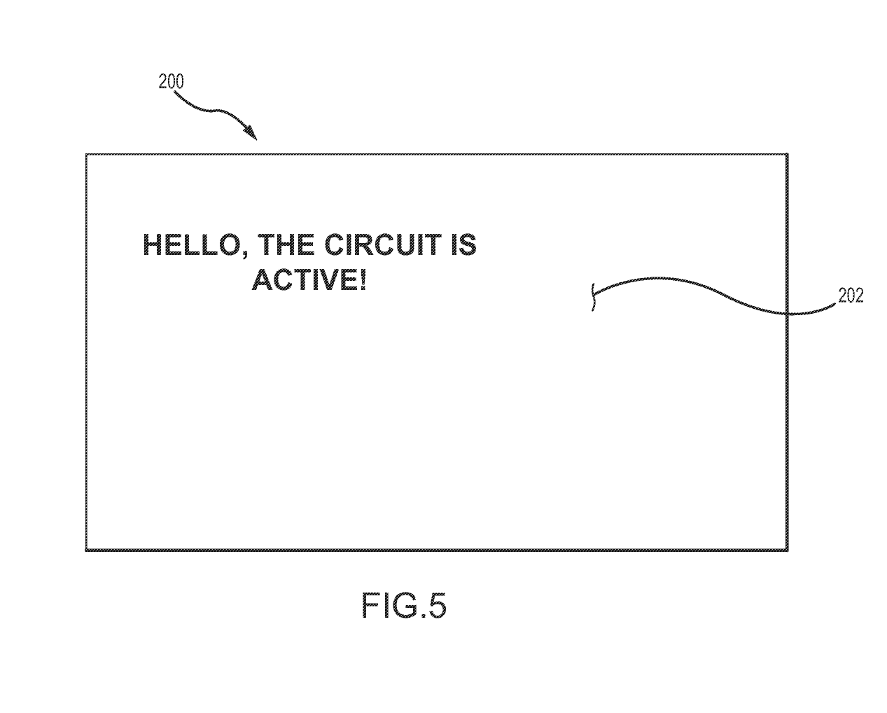

FIG. 5 is a top/bottom view of a circuit board 200 in an activated state. For this embodiment, the circuit board 200 leverages the thermochromic properties of the solder mask layer 202 for purposes of displaying a message or an indicator. In this regard, the electronic circuit underlying the thermochromic solder mask layer 202 is intentionally designed with conductive traces (and/or other controllable elements) that get hotter with activation of the electronic circuit. Thus, the circuit board 200 may include heating elements that are specifically configured and arranged in any desired layout, e.g., readable characters. Thus, only selected areas of the thermochromic solder mask layer 202 will change color when the electronic circuit is activated, because activation of the electronic circuit heats the conductive traces to a temperature that exceeds the color transition temperature of the solder mask layer 202.

For the embodiment depicted in FIG. 5, the thermochromic solder mask layer 202 has a nominal color associated with the inactive state of the electronic circuit. When inactive, the nominal color serves to obscure, hide, or otherwise make the underlying message difficult to read. When the electronic circuit is activated, however, the underlying conductive traces heat to a temperature that exceeds the color transition threshold of the thermochromic solder mask layer 202. As a result, specific sections of the solder mask layer 202 change from the nominal (obscuring) color to a distinguishable (visible) color. The circuit board 200 shown in FIG. 5 includes conductive traces or heating elements that are arranged to spell the words “HELLO, THE CIRCUIT IS ACTIVE!” when the temperature exceeds the intended threshold temperature. Of course, any type of message, indicator, design, or pattern could be generated using the thermochromic solder mask layer 202.

It should be appreciated that any thermochromic element, layer, or coating could be used in addition to, or in lieu of, a thermochromic solder mask layer to achieve equivalent results. Certain preferred embodiments, however, utilize a thermochromic solder mask layer because a solder mask layer is usually required when fabricating a printed circuit board. Accordingly, the heat sensitive color indication approach presented here can be implemented with no additional steps in the manufacturing process.

The embodiments described above use one thermochromic solder mask layer. In alternative embodiments, it may be desirable to apply one type of thermochromic solder mask material to one section of a circuit board, and another type of thermochromic solder mask material to a different section of the same circuit board. This approach could be followed if different temperature thresholds or ranges need to be monitored, if one section of the circuit board runs at a higher nominal temperature than another section of the circuit board, or to otherwise leverage the different color changing properties of different thermochromic substances.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. An electronic device comprising:
a printed circuit board comprising electrically conductive traces formed thereon; and
a thermochromic solder mask layer overlying at least the electrically conductive traces, wherein the thermochromic solder mask layer changes color in response to temperature changes associated with operation of the electronic device.

2. The electronic device of claim 1, wherein the thermochromic solder mask layer is formed on a surface of the printed circuit board.

3. The electronic device of claim 1, wherein the thermochromic solder mask layer comprises a thermochromic substance having thermochromic characteristics that are calibrated to indicate overheating of the electronic device.

4. The electronic device of claim 1, wherein the thermochromic solder mask layer comprises a thermochromic substance having thermochromic characteristics that are calibrated to indicate overheating of the electrically conductive traces.

5. The electronic device of claim 1, wherein the thermochromic solder mask layer comprises a thermochromic substance having a first color indicative of normal operating temperatures of the electronic device, and a second color indicative of unusually high operating temperatures of the electronic device.

6. The electronic device of claim 1, further comprising a semiconductor chip device electrically and physically coupled to the electrically conductive traces.

7. The electronic device of claim 1, wherein the thermochromic solder mask layer changes color at temperatures higher than a threshold temperature of approximately 70 degrees Celsius.

8. An electronic device comprising:
a circuit substrate;
at least one electronic component, device, or element on the circuit substrate; and
a layer of thermochromic material formed on the circuit substrate and in close proximity to the at least one electronic component, device, or element, wherein the layer of thermochromic material changes color in response to overheating of the at least one electronic component, device, or element.

9. The electronic device of claim 8, wherein the layer of thermochromic material comprises a solder mask layer applied to the circuit substrate.

10. The electronic device of claim 8, further comprising conductive traces formed on the circuit substrate, wherein the layer of thermochromic material is formed overlying the conductive traces.

11. The electronic device of claim 8, wherein the layer of thermochromic material exhibits a first color indicative of normal operating temperatures of the electronic device, and a second color indicative of unusually high operating temperatures of the electronic device.

12. The electronic device of claim 8, wherein the at least one electronic component, device, or element comprises a flip chip device.

13. The electronic device of claim 8, wherein the layer of thermochromic material changes color at temperatures higher than a threshold temperature of approximately 70 degrees Celsius.

14. An electronic device comprising:
a circuit substrate;
an electronic circuit formed on the circuit substrate;
a thermochromic solder mask layer overlying at least a portion of the electronic circuit, wherein the thermochromic solder mask layer changes color in response to activation of the electronic circuit.

15. The electronic device of claim 14, wherein the thermochromic solder mask layer changes color in response to temperature changes associated with activation of the electronic circuit.

16. The electronic device of claim 14, wherein the thermochromic solder mask layer comprises a thermochromic substance having thermochromic characteristics that are calibrated to indicate activation of the electronic circuit.

17. The electronic device of claim 14, wherein:
the electronic circuit comprises conductive traces;
the thermochromic solder mask layer covers the conductive traces; and
activation of the electronic circuit heats the conductive traces to a temperature that exceeds a color transition temperature of the thermochromic solder mask layer.
